(19) United States
(12) Patent Application Publication
(10) Pub. No.: US 2024/0096605 A1
(43) Pub. Date: Mar. 21, 2024

(54) BACKSIDE DEPOSITION FOR WAFER BOW MANAGEMENT

(71) Applicant: Applied Materials, Inc., Santa Clara, CA (US)

(72) Inventors: Arun Kumar Kotrappa, Karnataka (IN); CHANDRASHEKARA BAGINAGERE, Bengaluru (IN); RAMCHARAN SUNDAR, Tamil nadu (IN); SEYYED FAZELI, Santa Clara, CA (US); ANANTHA SUBRAMANI, San Jose, CA (US); SIYU ZHU, Sunnyvale, CA (US); AKHIL SINGHAL, Portland, OR (US); PHILIP ALLAN KRAUS, San Jose, CA (US)

(21) Appl. No.: 17/946,947

(22) Filed: Sep. 16, 2022

(51) Int. Cl. H01J 37/32; C23C 16/44; C23C 16/455; C23C 16/458; C23C 16/46; C23C 16/505; H01L 21/687

(52) U.S. Cl. CPC H01J 37/32715; C23C 16/4412; C23C 16/45565; C23C 16/4584; C23C 16/46; C23C 16/505; H01J 37/32449; H01J 37/32834; H01L 21/68742; H01J 37/32082; H01J 2237/20207; H01J 2237/20214; H01J 2237/332

(57) ABSTRACT

Embodiments disclosed herein include a semiconductor processing tool. In an embodiment, the semiconductor processing tool comprises a chamber, a pedestal in the chamber, and a first gas feed system on a first side of the pedestal. In an embodiment, the first gas feed system comprises a first exhaust line with a first valve to open and close the first exhaust line, and a first source gas feed line with a second valve to open and close the first source gas feed line. In an embodiment, the semiconductor processing tool further comprises a second gas feed system on a second side of the pedestal. In an embodiment, the second gas feed system comprises a second exhaust line with a third valve to open and close the second exhaust line, and a second source gas feed line with a fourth valve to open and close the second source gas feed line.

### BACKGROUND

### 1) Field

Embodiments relate to the field of semiconductor manufacturing and, in particular, to semiconductor processing tools for deposition of films on the backside of substrates for wafer bow management.

### 2) Description of Related Art

In semiconductor processing applications, one or more layers are deposited over a top surface of the substrate. The one or more layers may be stressed. The stress in the layers may be transferred into the substrate itself. This stress can result in warpage or bowing of the substrate. When the substrate is warped or bowed, the features on the substrate (e.g., pillars, lines, etc.) may be displaced. For example, pillars may be tilted towards each other or spread apart from each other, depending on the warpage. Additionally, chucking the substrate is made more difficult.

Accordingly, in some architectures a stress compensating film may be provided on the backside of the substrate. Ideally, the stress inherent in the stress compensating film is opposite from the stress provided by the layers on the top of the substrate. As such, the bowing or warpage is compensated in order to provide a substantially flat substrate for additional processing.

Providing backside layers over the substrate is not without issue. Particularly, the backside deposition process cannot cause particles or deposition on the front side of the substrate. Additionally, it is typically not desirable to flip the orientation of the substrate (i.e., flip the substrate upside down). As such existing deposition tools are generally not suitable for backside deposition processes.

### SUMMARY

Embodiments disclosed herein include a semiconductor processing tool. In an embodiment, the semiconductor processing tool comprises a chamber, a pedestal in the chamber, and a first gas feed system on a first side of the pedestal. In an embodiment, the first gas feed system comprises a first exhaust line with a first valve to open and close the first exhaust line, and a first source gas feed line with a second valve to open and close the first source gas feed line. In an embodiment, the semiconductor processing tool further comprises a second gas feed system on a second side of the pedestal. In an embodiment, the second gas feed system comprises a second exhaust line with a third valve to open and close the second exhaust line, and a second source gas feed line with a fourth valve to open and close the second source gas feed line.

Embodiments may also include a semiconductor processing tool that comprises a pedestal, a showerhead over the pedestal where the showerhead comprises a first plate with first holes and a second plate with second holes over the first plate, and lift pins configured to lift a substrate over the pedestal and the showerhead.

Embodiments may also include a semiconductor processing tool that comprises a chamber, a pedestal in the chamber, where the pedestal is coupled to an RF source, and a plate over the pedestal, where the plate is coupled to an electrical ground. In an embodiment, the semiconductor processing tool further comprises a gas distribution assembly between the pedestal and the plate. In an embodiment, the gas distribution assembly is configured to supply a process gas to a backside of a substrate.

### BRIEF DESCRIPTION OF THE DRAWINGS

FIG. 1A is a cross-sectional illustration of a semiconductor processing tool that includes a pair of gas feed systems in a first configuration, in accordance with an embodiment.

FIG. 1B is a cross-sectional illustration of the semiconductor processing tool in FIG. 1A in a second configuration in order to provide uniform backside film deposition, in accordance with an embodiment.

FIG. 2 is a cross-sectional illustration of a semiconductor processing tool that includes a backside showerhead configuration, in accordance with an embodiment.

FIG. 3A is a cross-sectional illustration of a semiconductor processing tool that includes a backside film deposition architecture, in accordance with an embodiment.

FIG. 3B is a cross-sectional illustration of a semiconductor processing tool that includes a bottom processing kit for backside deposition of a substrate, in accordance with an embodiment.

FIG. 3C is a cross-sectional illustration of a semiconductor processing tool that includes backside film deposition architecture with a front side inert gas flow around the overlying ground plate, in accordance with an embodiment.

FIG. 4A is a plan view illustration of the control of gas flow into two zones with an inner zone and outer zone, in accordance with an embodiment.

FIG. 4B is a plan view illustration of the control of gas flow into five zones with an inner zone and four outer zones, in accordance with an embodiment.

FIG. 5A is a perspective view illustration of a gas distribution assembly for radial gas distribution, in accordance with an embodiment.

FIG. 5B is a sectional illustration of an open valve for control of the gas distribution in a radial gas distribution assembly, in accordance with an embodiment.

FIG. 5C is a sectional illustration of a closed valve for control of the gas distribution in a radial gas distribution assembly.

FIG. 6 is a cross-sectional illustration of a semiconductor processing tool with a pedestal that can be tilted to provide a non-uniform distance to a ground plate, in accordance with an embodiment.

FIG. 7 illustrates a block diagram of an exemplary computer system that may be used in conjunction with a processing tool, in accordance with an embodiment.

### DETAILED DESCRIPTION

Systems described herein include semiconductor processing tools for deposition of films on the backside of substrates for wafer bow management. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

As noted above, depositing films on the backside of substrates can be useful for correction of bowed or warped substrates. However, the existing processing tools are typically designed to process the top side of substrates. That is, in order to form a backside film, the substrate needs to be flipped. This can damage the front side of the substrate, and is not desirable. Accordingly, embodiments disclosed herein include semiconductor processing tools that are configured to form a plasma below the substrate in order to deposit the backside film. In some embodiments, the processing gas is flown into the chamber from the sides. In other embodiments, a showerhead below the substrate faces the backside of the substrate in order to flow the processing gas into the chamber.

Additionally, it is to be appreciated that different types of warpage may need non-uniform backside film deposition. As such, embodiments disclosed herein include different methods and architectures in order to control the flow of processing gasses, control plasma parameters, or the like. In other embodiments, architectures may be particularly beneficial for providing uniform film deposition.

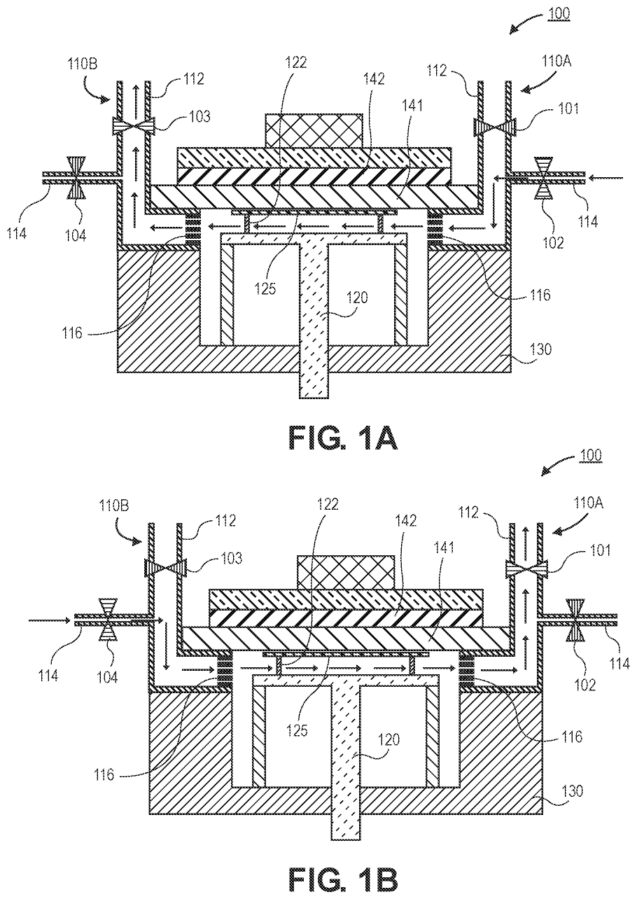

Referring now to FIG. 1A, a cross-sectional illustration of a semiconductor processing tool 100 for backside film deposition is shown, in accordance with an embodiment. In an embodiment, the semiconductor processing tool 100 in FIG. 1A is configured to provide a uniform backside film deposition. Particularly, a first configuration is shown in FIG. 1A in order to flow processing gas in a first direction across the substrate 125, and a second configuration is shown in FIG. 1B in order to flow processing gas in a second, opposite, direction across the substrate 125. While a dual direction gas feed system is shown in FIG. 1A, it is to be appreciated that a single direction gas feed system may be used if the pedestal 120 is rotatable.

In an embodiment, the semiconductor processing tool 100 includes a chamber 130. The chamber 130 may be any suitable material configured to support vacuum conditions within the chamber 130. The bottom portion of the chamber 130 is shown in FIG. 1A. However, additional portions of the chamber may also be included (e.g., sidewalls, portions of the lid, or the like).

In an embodiment, the semiconductor processing tool 100 may further comprise a first gas feed system 110A and a second gas feed system 110B. In an embodiment, the first gas feed system 110A and the second gas feed system 110B may be substantially similar to each other and provided on opposite sides of the semiconductor processing tool 100. In an embodiment, the gas feed systems 110A and 1108 may include exhaust lines 112 and process gas feed lines 114. Additionally, a set of valves may be provided on each gas feed system 110A and 1108. For example, in the first gas feed system 110A a first valve 101 may control gas flow into the exhaust line 112, and a second valve 102 may control gas flow into the chamber 130 from the gas feed line 114. Similarly, in the second gas feed system 1106, a third valve 103 may control gas flow into the exhaust line 112, and a fourth valve 104 may control gas flow into the chamber 130 from the gas feed line 114. In an embodiment, each of the gas feed systems 110A and 1108 may also include a showerhead 116 for distributing gasses into the chamber 130. In some embodiments, one or both of the showerheads 116 may be omitted.

In an embodiment, the semiconductor processing chamber 100 may include a pedestal 120. The pedestal 120 may be coupled to an RF source in order to strike the plasma between the substrate 125 and the top of the pedestal 120. The substrate 125 may be lifted up from the top of the pedestal 120 by lift pins 122. In some embodiments, the pedestal 120 may be a stationary pedestal 120. In other embodiments, the pedestal 120 may be rotatable. A rotating pedestal 120 may further improve film deposition uniformity in some instances. In a particular instance the inclusion of a rotating pedestal 120 may allow for a single sided gas feed system (e.g., a semiconductor processing tool 100 with a single gas feed line 110A) to be used while still enabling uniform film deposition.

In an embodiment, the substrate 125 may be any type of substrate typically processed in semiconductor manufacturing equipment. In a particular embodiment, the substrate 125 may be a wafer (e.g., a silicon wafer or any other semiconductor wafer). The substrate 125 may have any form factor (e.g., 150 mm, 200 mm, 300 mm, 450 mm, or the like). Other materials and form factors may also be used for the substrate 125 (e.g., glass substrates, sapphire substrates, or the like). That is, the substrate 125 may be any substrate that may benefit from the inclusion of a backside film deposition.

In an embodiment, the backside film that is deposited may be a film that can induce a high level of stress into the substrate 125. In a particular embodiment, the backside film may include silicon and nitrogen (e.g., silicon nitride). The silicon nitride film may be a high temperature film. For example, the backside film may be deposited at a temperature of 500° C. or greater, or 700° C. or greater. The high temperature may be implemented in part by using a pedestal 120 that can be heated. Alternatively (or in addition to a heated pedestal), an array of lamps 142 may be provided above the substrate 125 in order to heat the substrate 125.

In an embodiment, a grounded plate 141 may be provided over the substrate 125. The grounded plate 141 may be coupled to an electrical ground in order to enable the formation of a plasma in the chamber 130. The grounded plate 141 may also be a showerhead in some embodiments. For example, an inert process gas may be flown into the chamber through the grounded plate 141 in some embodiments. The grounded plate 141 may be relatively close to the top surface of the substrate 125. The minimal spacing between the grounded plate 141 and the substrate 125 (and the flow of the inert gas) may assist in preventing the formation of a plasma between the grounded plate 141 and the top surface of the substrate 125. For example, the grounded plate 141 may be approximately 10 mm or less, approximately 5 mm or less, or approximately 1 mm or less away from the top surface of the substrate 125. Preventing the formation of a plasma above the substrate 125 keeps the top surface of the substrate pristine and undamaged during the backside film deposition process.

In the embodiment shown in FIG. 1A, a first tool configuration is provided. The first tool configuration enables the flow of processing gasses from the right of the substrate 125 to the left of the substrate 125, as indicated by the arrows. Particularly, the first tool configuration includes the first valve 101 being closed and the second valve being opened. This allows the processing gas to enter the chamber through the first gas feed system 110A. The first tool configuration also includes the third valve 103 being opened and the fourth valve 104 being closed. This allows for the processing gas to be evacuated from the chamber 130 through the second gas feed system 110B.

In FIGS. 1A and 1B, the second valve 102 and the fourth valve 104 are shown as being two separate valves. However, in some embodiments, a single valve may be used in order to selectively flow the processing gas into either the first gas feed system 110A or the second gas feed system 110B. Additionally, the two separate exhaust lines 112 may be coupled together outside of the illustration shown in FIGS. 1A and 1B. That is, a single exhaust system may be used to evacuate the chamber 130.

Referring now to FIG. 1B, a cross-sectional illustration of the semiconductor processing tool 100 in a second tool configuration is shown, in accordance with an embodiment. The second tool configuration may be substantially opposite from the first tool configuration. As such, the processing gas may flow from the left of the substrate 125 to the right of the substrate 125, as indicated by the arrows. In an embodiment, the second tool configuration may include the first valve 101 being open and the second valve 102 being closed. Additionally, the third valve 103 is closed, and the fourth valve 104 is open. As such, the processing gas may flow into the chamber 130 from the second gas feed system 110B, and the gas may be evacuated from the chamber 130 by the first gas feed system 110A.

In an embodiment, the semiconductor processing tool 100 may switch between the first tool configuration and the second tool configuration in order to uniformly deposit a backside film onto the substrate 125. In a particular embodiment, the semiconductor processing tool 100 may be in the first tool configuration for a first duration, and the semiconductor processing tool 100 may be switched to the second tool configuration for a second duration. The first duration and the second duration may be substantially similar to each other. In other embodiments, the semiconductor processing tool 100 may be switched back and forth between the first tool configuration and the second tool configuration. In yet another embodiment, either the first tool configuration or the second tool configuration may be selected, and the substrate 125 may be rotated. In an embodiment, the rotation may be at a constant angular speed while varying gas flows in order produce a uniform backside film or an intentional non-uniform backside film.

While embodiments with a uniform backside film are possible, it is also possible to form non-uniform backside films. For example, the first duration may be greater than the second duration in order to form a thicker backside film on one side of the substrate. Alternatively, only one of the first tool configuration or the second tool configuration may be selected without rotating the substrate 125. In other embodiments, the rotation may be at a varying angular speed and constant (or varying) process gas flows may be used to produce intentional non-uniform backside film deposition.

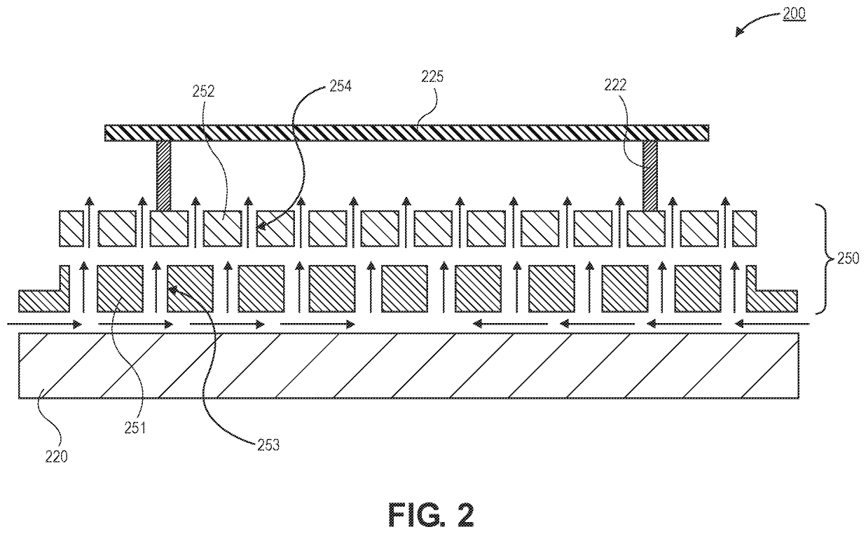

Referring now to FIG. 2, a cross-sectional illustration of a portion of a semiconductor processing tool 200 is shown, in accordance with an additional embodiment. In contrast to the cross-flow of processing gasses in FIGS. 1A and 1B, the processing gas is flown into the chamber from below the substrate 225. Flowing the processing gas from the bottom of the substrate 225 may allow for more uniform backside film deposition in some embodiments. Particularly, there may not be a need to rotate the substrate 225 or switch configurations of the semiconductor processing tool 200 in order to provide the desired backside film uniformity.

In an embodiment, the semiconductor processing tool may comprise a pedestal 220. The pedestal 220 may be coupled to an RF source in order to strike a plasma between the substrate 225 and the pedestal 220. In an embodiment, the pedestal 220 may further comprise a heater in order to provide high temperature backside films. The grounded plate for completion of the circuit is omitted for simplicity. But it is to be appreciated that an electrically grounded plate (e.g., showerhead) may be provided above the substrate 225. Lift pins 222 may be provided to support the substrate 225 in a raised position relative to the pedestal 220.

In an embodiment, a showerhead 250 may be provided between the substrate 225 and the pedestal 220. In an embodiment, the showerhead 250 may include a pair of plates 251 and 252. Though, it is to be appreciated that a showerhead with a single plate configuration may also be used in some embodiments. In an embodiment, the processing gas (as indicated by the arrows) may flow between the pedestal 220 and the first plate 251. The gas may flow up through holes 253 in the first plate 251. A gap may be provided between the first plate 251 and the second plate 252 in order to allow for further distribution of the processing gas. In an embodiment, the processing gas then flows through holes 254 in the second plate 252 in order to enter the chamber.

In an embodiment, the number of holes 253 may be different than the number of holes 254. For example, there may be fewer holes 253 than there are holes 254. Additionally, a diameter of the holes 253 may be larger than a diameter of the holes 254. The positioning of the holes 253 relative to the holes 354 may also be offset in order to enhance the spreading of the processing gas before it enters the chamber below the substrate 225.

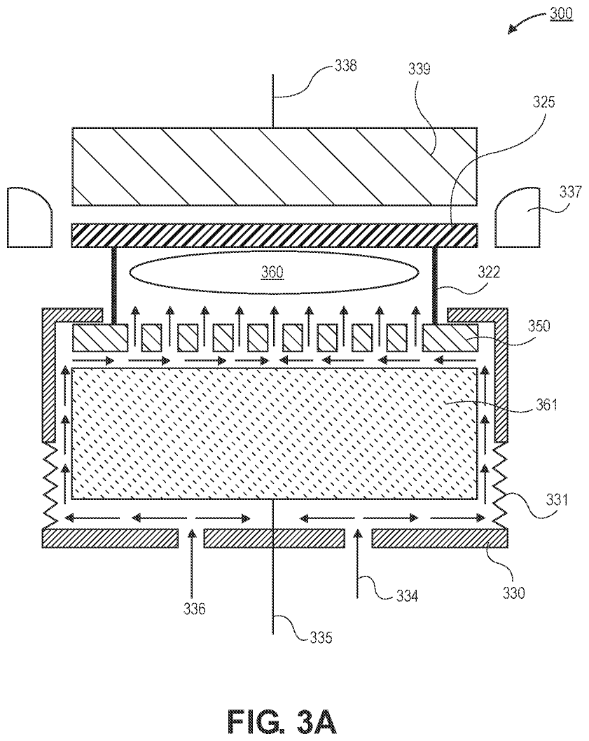

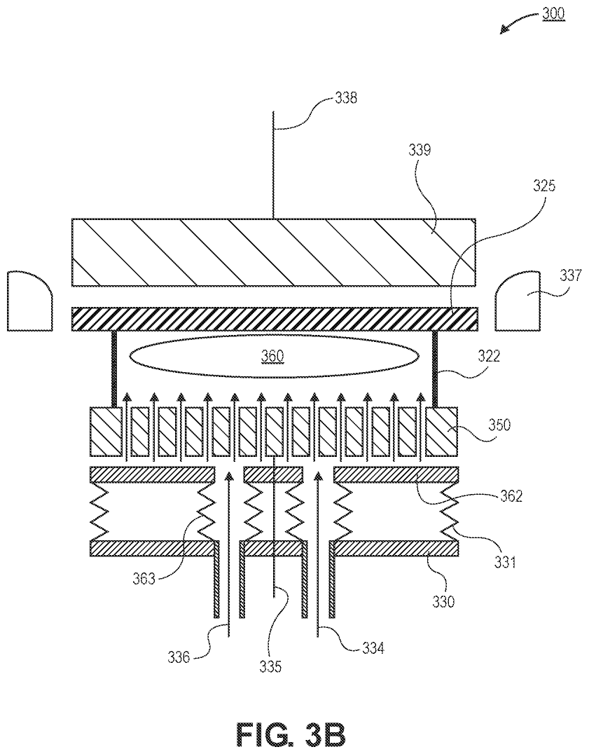

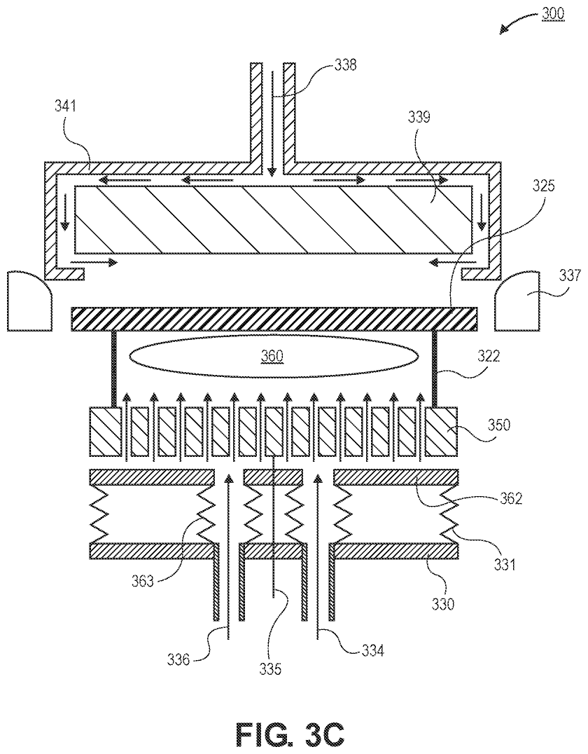

Referring now to FIG. 3A, a cross-sectional illustration of a semiconductor processing tool 300 is shown, in accordance with an embodiment. In an embodiment, the semiconductor processing tool 300 may comprise a chamber 330. In an embodiment, the chamber 330 may include a bellows 331 to enable raising and lowering a pedestal 361. In an embodiment, the pedestal 361 may comprise a heater or the like. Additionally, the pedestal 361 may be coupled to a an RF source 335, such as a low frequency RF and/or a high frequency RF. In an embodiment, a showerhead 350 may be provided over the pedestal 361. The showerhead 350 may include passages for gas (indicated by arrows) to enter the processing region to form a plasma 360. In an embodiment, the gas may flow around the pedestal 361. For example, gas sources 334 and 336 may be provided below the pedestal 360. The gas source 334 may be a processing gas, and the gas source 336 may be a dilution gas (e.g., an inert gas). The gas sources 334 and 336 may mix before passing through the showerhead 350 into the processing region between the substrate 325 and the showerhead 350.

In an embodiment, the showerhead 350 may be any suitable material. In a particular embodiment, the showerhead 350 may be a ceramic showerhead 350. In other embodiments, the showerhead 350 may include a conductive material such as aluminum or the like. Additionally, while a showerhead 350 with a single plate is shown, it is to be appreciated that multi-plate showerheads 350 (similar to the embodiment described above) may be used in accordance with an embodiment. Additionally, while described as a showerhead, the component 350 may be any suitable process kit that allows gas to flow into the processing region of the chamber 330.

In an embodiment, the substrate 325 may be supported up above the showerhead 350 by lift pins 322. The substrate 325 may be raised up to the height of a process ring 337. The process ring 337 may surround a perimeter of the substrate 325 when the substrate is in a raised position. In an embodiment, an overhead showerhead 339 may be provided over a top surface of the substrate 325. The overhead showerhead 339 may be electrically grounded in order to complete the circuit for forming the plasma 360. The overhead showerhead 339 may be fed an inert gas 338. The inert gas flows through the overhead showerhead 339 in order to provide an inert environment over the top surface of the substrate 325 during processing. Additionally, in order to prevent plasma striking above the substrate 325, a distance between the top of the substrate 325 and a bottom of the overhead showerhead 339 may be approximately 10 mm or less, approximately 5 mm or less, or approximately 1 mm or less. As such, damage to the front side of the substrate 325 is minimized. The overhead showerhead 339 may be heated in order to provide high temperature deposition of the film on the backside of the substrate 325.

Referring now to FIG. 3B, a cross-sectional illustration of a semiconductor processing tool 300 is shown, in accordance with an additional embodiment. As shown, gas inlets 334 and 336 may pass through the chamber 330, and a bellows 363 couples the gas inlets 334 and 336 to holes through the isolator 362. The isolator 362 may also be coupled to the chamber 330 through an outer bellows 331. The bellows 363 and 331 enable vertical displacement of the system. In an embodiment, a showerhead or process kit 350 may be provided over the isolator 362. Gas from gas inlets 334 (processing gas) and 336 (dilution gas) may mix before passing through the showerhead 350 into the processing region of the chamber 330 where the plasma 360 is struck.

In an embodiment, a substrate 325 is supported by lift pins 322 in a raised position to provide room for the plasma 360 between the substrate 325 and the showerhead 350. In an embodiment, the substrate 325 may be surrounded by a process ring 337. An overhead showerhead 339 may be provided over the substrate 325. The overhead showerhead 339 may be fed with an inert gas 338. The overhead showerhead 339 may be electrically grounded in some embodiments. Additionally, the showerhead 339 may be heated in order to provide high temperature film deposition on the backside surface of the substrate 325.

Referring now to FIG. 3C, a cross-sectional illustration of a semiconductor processing tool 300 is shown, in accordance with an additional embodiment. In an embodiment, the semiconductor processing tool 300 in FIG. 3C may be substantially similar to the semiconductor processing tool 300 shown in FIG. 3B, with the exception of the overhead grounded feature. Instead of providing a showerhead (e.g., a perforated plate), the overhead feature may include a non-perforated plate 339. In order to supply an inert gas 338 to the top side of the substrate 325, an enclosure 341 may be provided around the non-perforated plate 339. As shown by the arrows, the inert gas 338 flows around the perforated plate 339 in order to reach the processing region of the chamber 330. In an embodiment, the non-perforated plate 339 may be electrically grounded. Additionally, the non-perforated plate 339 may include a heater in order to allow for high temperature film deposition on the backside of the substrate 325.

In the embodiments described above, processing conditions may be maintained in order to deposit a backside film that is substantially uniform over the backside surface of the substrate. However, in some embodiments the stress needs to be applied in a non-uniform manner in order to correct certain types of bowing (e.g., a saddle shaped bow). In such embodiments, modifications to the semiconductor processing tool may be provided in order to control the flow of gas into the chamber in order to deposit a non-uniform backside film.

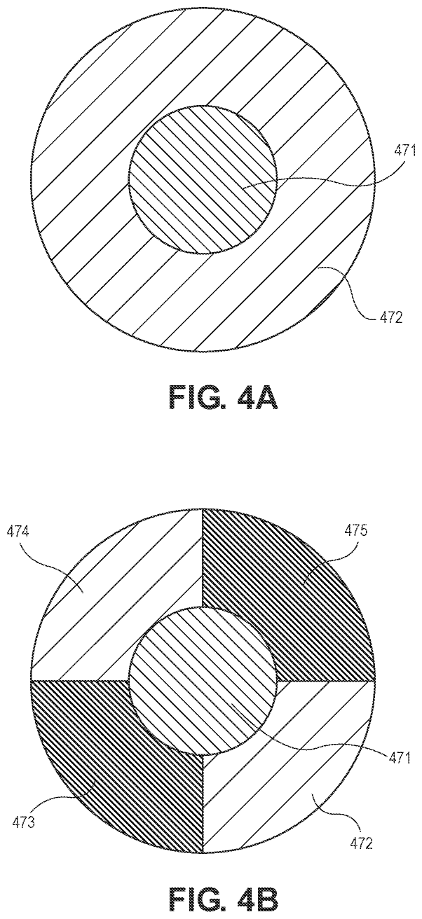

Referring now to FIG. 4A, a processing tool with dual zone control of film thickness is illustrated. As shown, a first zone 471 is provided at a center of the substrate and a second zone 472 is provided radially around the first zone. Such an embodiment may allow for the center of the substrate to have a film with different thicknesses at the center and the edge of the substrate. The different zones 471 and 472 may be controlled with any combination of valves or the like in order to provide a desired film profile.

Similarly, in FIG. 4B, a processing tool with five control zones 471-475 is shown, in accordance with an embodiment. The use of five zones allows for even greater control of the backside film profile. In a particular embodiment, the five control zones 471-475 may be used in order to reduce the bowing in a saddle shaped substrate.

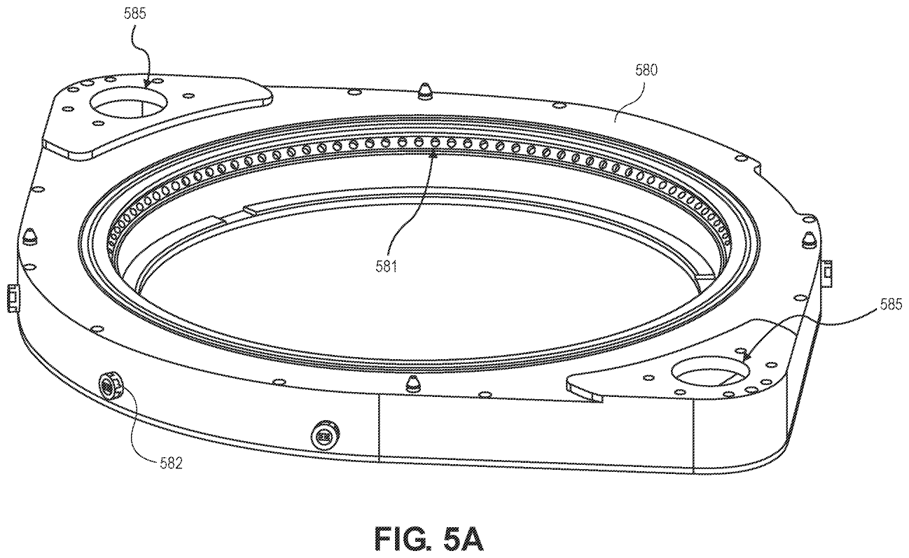

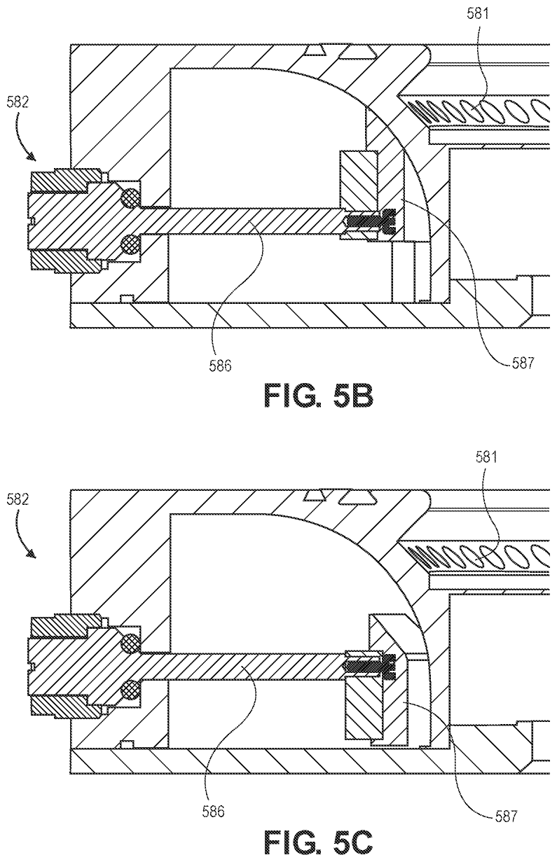

Referring now to FIG. 5A, a perspective view illustration of a showerhead 580 that enables radial distribution of gasses into the chamber is shown, in accordance with an embodiment. As shown, the showerhead may have inlets 585 that feed a plurality of holes 581 around a perimeter of the showerhead 580. In addition to controlling the flow of gasses into the inlets 585, valves 582 can be used to control the flow in certain sections of the showerhead 580. For example, by fully opening, fully closing, or partially closing the valves 582, the flow of processing gas through the plurality of holes 581 can be modulated. In the illustrated embodiment, a total of six valves 582 are shown (three that are visible in the front and three in the back, of which one is visible). However, it is to be appreciated that any number of valves 582 may be used in order to provide the desired control to the semiconductor processing tool.

Referring now to FIG. 5B, a sectional illustration of the valve 582 in an open position is shown, in accordance with an embodiment. As shown, the outer portion of the valve 582 may be coupled to a plate 587 that is adjacent to the holes 581. By turning the outer portion of the valve 582, the plate 587 may be moved up and down. In the state shown in FIG. 5B, the plate is completely removed from the holes 581 (e.g., positioned below the holes 581). As such, the processing gas may freely flow through the holes 581.

Referring now to FIG. 5C, a sectional illustration of the valve 582 in a closed position is shown, in accordance with an embodiment. As shown, the plate 587 is pressed up against the holes 581 in order to prevent flow of gas through the holes 581. While a fully open configuration (FIG. 5B) and a fully closed configuration (FIG. 5C) is shown, it is to be appreciated that the valves 582 may be partially closed as well. In such an embodiment, the flow of the processing gas is restricted, but not fully stopped.

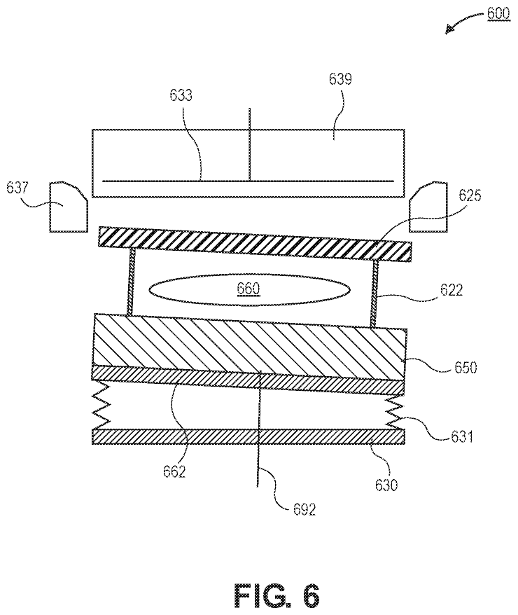

Referring now to FIG. 6, a cross-sectional illustration of a semiconductor processing tool 600 is shown, in accordance with yet another embodiment. Instead of controlling the flow of processing gasses, the embodiment shown in FIG. 6 uses a modulation in the gap between the RF source and the ground plate 633. For example, the showerhead 639 includes a grounded plate 633. Though, it is to be appreciated that the showerhead 639 may be conductive and the entire showerhead 639 may be grounded.

Additionally, the process kit 650 (e.g., showerhead) may be coupled to an RF source 692. Instead of being raised and lowered in a planar manner, the process kit may be tilted. The tilt may be accommodated by the bellows 631 of the chamber 630. In an embodiment, the tilted isolator 662 and process kit 650 may result in one side of the process kit 650 being closer to the ground plate 633. As such, the substrate 625 (that is supported by the lift pins 622 and within the process ring 637) will experience a non-uniform plasma 660 across the surface of the substrate. The non-uniform plasma 660 will result in a non-uniform deposition of the backside film.

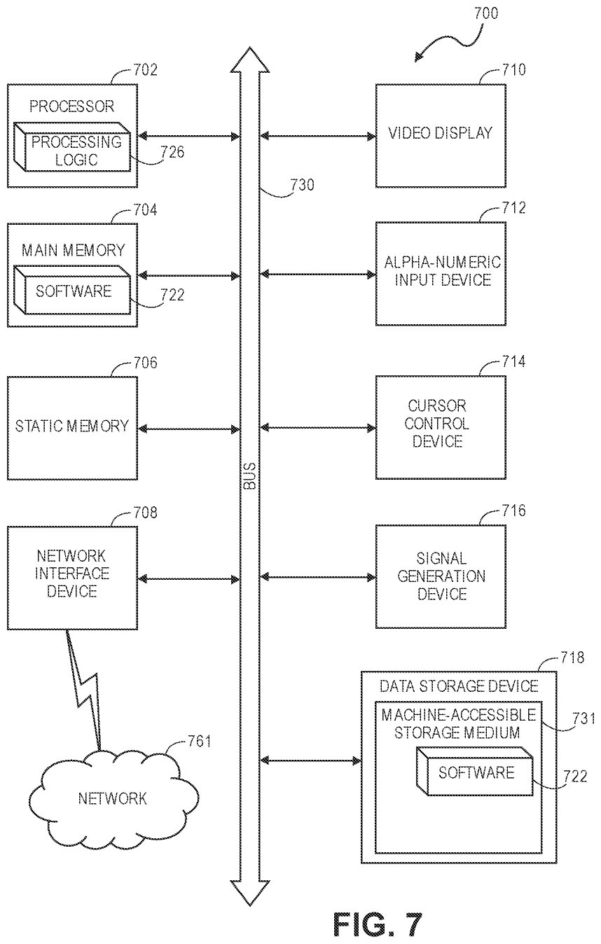

Referring now to FIG. 7, a block diagram of an exemplary computer system 700 of a processing tool is illustrated in accordance with an embodiment. In an embodiment, computer system 700 is coupled to and controls processing in the processing tool. Computer system 700 may be connected (e.g., networked) to other machines in a Local Area Network (LAN), an intranet, an extranet, or the Internet. Computer system 700 may operate in the capacity of a server or a client machine in a client-server network environment, or as a peer machine in a peer-to-peer (or distributed) network environment. Computer system 700 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 700, the term “machine” shall also be taken to include any collection of machines (e.g., computers) that individually or jointly execute a set (or multiple sets) of instructions to perform any one or more of the methodologies described herein.

Computer system 700 may include a computer program product, or software 722, having a non-transitory machine-readable medium having stored thereon instructions, which may be used to program computer system 700 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 700 includes a system processor 702, a main memory 704 (e.g., read-only memory (ROM), flash memory, dynamic random access memory (DRAM) such as synchronous DRAM (SDRAM) or Rambus DRAM (RDRAM), etc.), a static memory 706 (e.g., flash memory, static random access memory (SRAM), etc.), and a secondary memory 718 (e.g., a data storage device), which communicate with each other via a bus 730.

System processor 702 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 702 may also be one or more special-purpose processing devices such as an application specific integrated circuit (ASIC), a field programmable gate array (FPGA), a digital signal system processor (DSP), network system processor, or the like. System processor 702 is configured to execute the processing logic 726 for performing the operations described herein.

The computer system 700 may further include a system network interface device 708 for communicating with other devices or machines. The computer system 700 may also include a video display unit 710 (e.g., a liquid crystal display (LCD), a light emitting diode display (LED), or a cathode ray tube (CRT)), an alphanumeric input device 712 (e.g., a keyboard), a cursor control device 714 (e.g., a mouse), and a signal generation device 716 (e.g., a speaker).

The secondary memory 718 may include a machine-accessible storage medium 732 (or more specifically a computer-readable storage medium) on which is stored one or more sets of instructions (e.g., software 722) embodying any one or more of the methodologies or functions described herein. The software 722 may also reside, completely or at least partially, within the main memory 704 and/or within the system processor 702 during execution thereof by the computer system 700, the main memory 704 and the system processor 702 also constituting machine-readable storage media. The software 722 may further be transmitted or received over a network 720 via the system network interface device 708. In an embodiment, the network interface device 708 may operate using RF coupling, optical coupling, acoustic coupling, or inductive coupling.

While the machine-accessible storage medium 732 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A semiconductor processing tool, comprising:
a chamber;
a pedestal in the chamber;
a first gas feed system on a first side of the pedestal, wherein the first gas feed system comprises:
a first exhaust line with a first valve to open and close the first exhaust line; and
a first source gas feed line with a second valve to open and close the first source gas feed line; and
a second gas feed system on a second side of the pedestal, wherein the second gas feed system comprises:
a second exhaust line with a third valve to open and close the second exhaust line; and
a second source gas feed line with a fourth valve to open and close the second source gas feed line.

2. The semiconductor processing tool of claim 1, further comprising:
lift pins configured to extend out of the pedestal to lift a substrate.

3. The semiconductor processing tool of claim 1, further comprising:
a first showerhead at an entrance of the first gas feed system; and
a second showerhead at an entrance to the second gas feed system.

4. The semiconductor processing tool of claim 3, wherein the first showerhead and the second showerhead are substantially similar to each other.

5. The semiconductor processing tool of claim 1, further comprising:
a grounded electrode over the pedestal.

6. The semiconductor processing tool of claim 5, wherein the pedestal is coupled to an RF source.

7. The semiconductor processing tool of claim 1, further comprising:
a heater over the pedestal.

8. The semiconductor processing tool of claim 1, further comprising:
an inert gas line that is configured to flow an inert gas into the chamber above the pedestal.

9. The semiconductor processing tool of claim 8, wherein the inert gas line flows the inert gas through a showerhead over the pedestal.

10. The semiconductor processing tool of claim 9, wherein a substrate is supported between the showerhead over the pedestal and the pedestal, wherein a plasma is struck below the substrate.

11. The semiconductor processing tool of claim 1, wherein the substrate is configured to be rotated at a constant angular speed or a varying angular speed.

12. A semiconductor processing tool, comprising:
a pedestal;
a showerhead over the pedestal wherein the showerhead comprises a first plate with first holes and a second plate with second holes over the first plate; and
lift pins configured to lift a substrate over the pedestal and the showerhead.

13. The semiconductor processing tool of claim 12, wherein a gap is provided between the first plate and the second plate.

14. The semiconductor processing tool of claim 12, wherein the showerhead distributes a process gas across a bottom surface of a substrate supported by the lift pins.

15. The semiconductor processing tool of claim 12, wherein the pedestal is coupled to an RF source.

16. A semiconductor processing tool, comprising:
a chamber;
a pedestal in the chamber, wherein the pedestal is coupled to an RF source;
a plate over the pedestal, wherein the plate is coupled to an electrical ground; and
a gas distribution assembly between the pedestal and the plate, wherein the gas distribution assembly is configured to supply a process gas to a backside of a substrate.

17. The semiconductor processing tool of claim 16, wherein the gas distribution assembly is configured to have two or more zones, wherein each zone is configured to have independently controllable gas flow rates.

18. The semiconductor processing tool of claim 17, wherein the two or more zones include a center zone, and four peripheral zones outside of the center zone.

19. The semiconductor processing tool of claim 16, wherein the pedestal is configured to be tilted so a first side of the pedestal is closer to the plate than a second side of the pedestal.

20. The semiconductor processing tool of claim 16, further comprising:
a plurality of valves coupled to the gas distribution assembly, wherein the plurality of valves are independently controllable to modify a gas flow out of the gas distribution assembly.
